(19) United States
(12) Patent Application Publication
(10) Pub. No.: US 2018/0233428 A1
(43) Pub. Date: Aug. 16, 2018

(54) HEAT DISSIPATION ASSEMBLY

(71) Applicant: JOINSET CO., LTD., Ansan-si (KR)

(72) Inventor: Sun-Ki Kim, Gunpo-si (KR)

(73) Assignee: JOINSET CO., LTD.

(21) Appl. No.: 15/892,563

(22) Filed: Feb. 9, 2018

(30) Foreign Application Priority Data
Feb. 15, 2017 (KR) 10-2017-0020751
Nov. 22, 2017 (KR) 10-2017-0156547

(51) Int. Cl. H01L 23/367; H01L 23/552; F28F 3/02

(52) U.S. Cl. CPC H01L 23/3675; F28F 3/02; H01L 23/552

(57) ABSTRACT

A heat dissipation assembly capable of quickly dissipating heat emitted by a heating source of an electronic communication apparatus. The heat dissipation assembly includes a metal pad which includes one surface fixed to a surface of a metal case and the other surface with a protrusion, a first thermal interface material which adheres to a top surface of the protrusion, and a second thermal interface material which adheres to a bottom surface of the protrusion. Here, heat generated by the heating source is transferred to the case through a first heat transfer path formed of the first thermal interface material and the metal pad and a second heat transfer path formed of the first thermal interface material, the metal pad, and the second thermal interface material, to be cooled and dissipate.

### REFERENCE TO RELATED APPLICATIONS

This application claims the priority benefit of Korean Patent Application No. 10-2017-0020751 filed on Feb. 15, 2017 and Korean Patent Application No. 10-2017-0156547 filed on Nov. 22, 2017, the entire contents of which are incorporated herein by reference.

### FIELD OF THE INVENTION

The present invention relates to a heat dissipation assembly, and more particularly, to a technology capable of quickly dissipating heat emitted by a heating source of an electronic communication apparatus.

### BACKGROUND OF THE INVENTION

As electronic communication apparatuses including cellular phones have been advanced and highly functional, a processing speed of a microprocessor increases such that heating rears up as a big problem.

Although a thermal interface material is generally used in order to quickly dissipate heat generated by a general microprocessor to the outside, there is a limit in heat conductivity. Also, when a thermal interface material including a metal having high heat conductivity such as copper is used, it is difficult to stably install the thermal interface material between a microprocessor and a metal case.

FIG. 1 is a view illustrating an example in which a general heat dissipation assembly is applied.

A heat dissipation assembly 30 intervenes between a metal case 50 and a heating source 20 mounted on a circuit board 10 and includes a metal pad 32 of a copper alloy and coupled to the case 50 and thermal interface materials 34 formed of thermally conductive silicone rubbers and mounted on the metal pad 32.

Heat generated by the heating source 20 is transferred to the metal case 50 through the thermal interface materials 34 and the metal pad 32 to be cooled and dissipate.

When the general heat dissipation assembly 30 including the metal pad 32 and the thermal interface materials 34 mounted on the metal pad 32 is used, it is easy to mount the general heat dissipation assembly 30 on the metal case 50 using a surface mounting method and the like.

However, according to the general heat dissipation assembly, heights of the thermal interface materials are determined corresponding to a gap between the case and the heating source. Here, when widths of the thermal interface materials decrease and heights thereof increase, the thermal interface materials are vulnerable to a laterally applied external shock.

Particularly, when thermal interface materials having low hardness and very soft are used, a physical force thereof is weak and it is difficult to apply the thermal interface materials.

Also, since the thermal interface materials and the metal pad are configured as a single body having a flat structure, it is difficult to provide a variety of thermal, electrical, and mechanical functions.

Also, since mechanical contact at an interface between the metal pad and the metal case is inadequate, heat transfer is inefficiently performed.

### SUMMARY OF THE INVENTION

Therefore, it is an aspect of the present invention to provide a heat dissipation assembly capable of quickly and reliably dissipating heat generated by a heating source.

It is another aspect of the present invention to provide a heat dissipation assembly which easily withstand a laterally applied external shock and to which a soft thermal interface material is applicable.

It is another aspect of the present invention to provide a heat dissipation assembly which easily provides a variety of thermal, electrical, and mechanical functions.

It is another aspect of the present invention to provide a heat dissipation assembly which is modulated to be simply mounted between a metal case and a heating source such that manufacturing efficiency thereof is high.

It is another aspect of the present invention to provide a heat dissipation assembly which is easy to be automatically mounted.

It is another aspect of the present invention to provide a heat dissipation assembly which is easy to shield electromagnetic interference.

According to one aspect of the present invention, a heat dissipation assembly, applied to a heating source mounted on a circuit board, includes a metal pad which has one surface protruding to form a protrusion and the other surface fixed to an object, a first thermal interface material which adheres to the protrusion at the one surface, and a second thermal interface material which adheres to the protrusion at the other surface. Here, the first thermal interface material includes flexibility and elasticity and comes into elastic contact with a surface of the heating source. Also, heat generated by the heating source is transferred to the object through a first heat transfer path formed of the first thermal interface material and the metal pad and a second heat transfer path formed of the first thermal interface material, the metal pad, and the second thermal interface material, to be cooled and dissipate.

According to another aspect of the present invention, a heat dissipation assembly, applied to a heating source mounted on a circuit board and a shield can which is mounted on the circuit board to enclose the heating source and has an opening at a top surface, includes a metal pad which has one surface protruding to form a protrusion and the other surface fixed to an object, a first thermal interface material which adheres to the protrusion at the one surface, a second thermal interface material which adheres to the protrusion at the other surface, and an elastic gasket configured to form a closed loop or a partially opened loop along an edge on surface of the metal pad and comes into contact with the shield can. Here, the first thermal interface material includes flexibility and elasticity and comes into elastic contact with a surface of the heating source. Also, heat generated by the heating source is transferred to the object through a first heat transfer path formed of the first thermal interface material and the metal pad and a second heat transfer path formed of the first thermal interface material, the metal pad, and the second thermal interface material, to be cooled and dissipate.

According to still another aspect of the present invention, a heat dissipation assembly, applied to a heating source mounted on a circuit board, includes a metal pad which has one surface protruding to form a protrusion and the other surface fixed to an object, a first thermal interface material which adheres to the protrusion at the one surface, and a second thermal interface material which adheres to the protrusion at the other surface. Here, the first thermal interface material includes flexibility and elasticity and comes into elastic contact with a surface of the heating source, and the second thermal interface material is formed to extend toward an edge of the metal pad. Also, heat generated by the heating source is transferred to the object through a heat transfer path formed of the first thermal interface material, the metal pad, and the second thermal interface material, to be cooled and dissipate.

The metal pad may be fixed to the object through a thermally conductive adhesive tape, a thermally conductive adhesive, soldering, a screw, or welding.

The protrusion may be formed to be integrated with the metal pad by a drawing mold and a press.

The first thermal interface material may be formed to extend toward an edge of the metal pad.

The elastic gasket may be one of an electrically conductive rubber, an electrically conductive gasket formed of an electrically conductive film, an electrically conductive gasket formed of electrically conductive fibers, and an electrically conductive sponge. The electrically conductive rubber may be formed by curing an electrically conductive liquid rubber corresponding to the electrically conductive rubber and attached to the metal pad.

The metal pad may include any one of copper, a copper alloy, aluminum, and an aluminum alloy and may be plated with nickel, tin, silver, or gold at an outer surface thereof.

At least one of the first and second thermal interface materials may be self-adhesive. A surface area of the first thermal interface material may be larger than a surface area of the second thermal interface material. A height of the first thermal interface material may be higher than a height of the second thermal interface material.

At least one of the first and second thermal interface materials may include a silicone rubber including thermally conductive carbon fibers having a length longer than a diameter.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view illustrating an example in which a general heat dissipation assembly is applied;

FIG. 2A is a perspective view of a heat dissipation assembly according to one embodiment of the present invention;

FIG. 2B is a cross-sectional view taken along A-A in FIG. 2A;

FIG. 3 is a view illustrating an example in which the heat dissipation assembly according to one embodiment is applied;

FIG. 4A is a perspective view of a heat dissipation assembly according to another embodiment of the present invention;

FIG. 4B is a cross-sectional view taken along A-A in FIG. 4A;

FIG. 5 is a view illustrating an example in which the heat dissipation assembly according to another embodiment is applied; and

FIGS. 6A to 6C are views of a plurality of heat dissipation assemblies according to other embodiments.

### DETAILED DESCRIPTION OF THE INVENTION

The technical terms used herein are merely for explaining particular embodiments and are not intended to limit the present invention. Also, the technical terms used herein, unless defined otherwise, should be interpreted as having meanings generally understood by one of ordinary skill in the art and not be interpreted as having excessively comprehensive meanings or excessively reduced meanings. Also, when the technical terms used herein are wrong technical terms which can not clearly represent the concept of the present invention, they should be understood while being replaced by technical terms capable of being properly understood by those skilled in the art. Also, general terms used herein should be interpreted according to the defined in a dictionary or according to back-and-forth context and not be understood as having excessively reduced meanings.

Hereinafter, embodiments of the present invention will be described in detail with reference to the attached drawings.

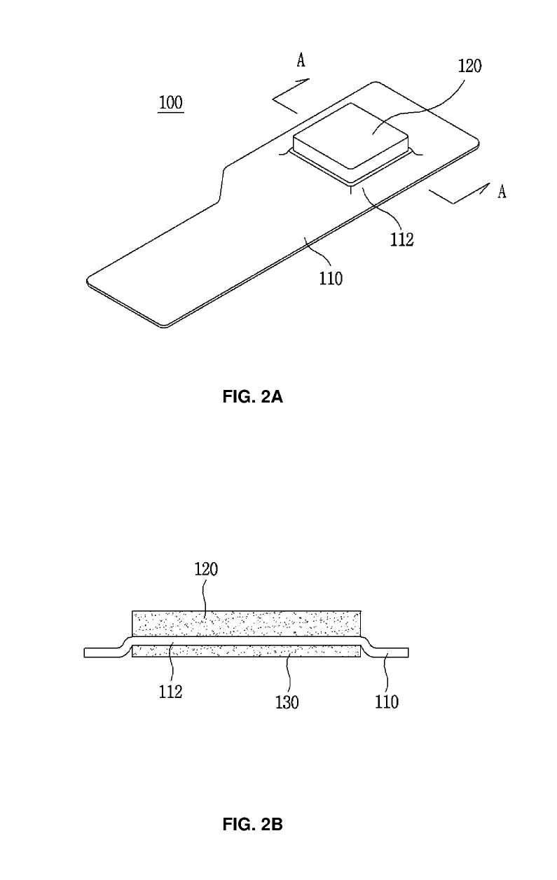

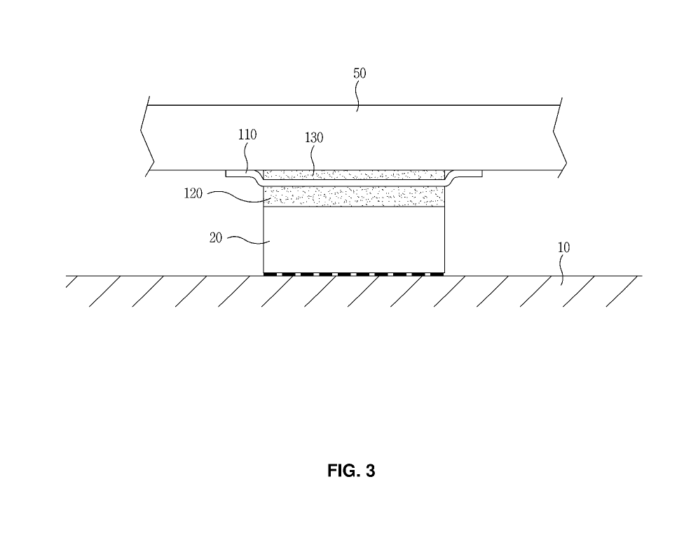

FIG. 2A is a perspective view of a heat dissipation assembly according to one embodiment of the present invention, FIG. 2B is a cross-sectional view taken along A-A in FIG. 2A, and FIG. 3 is a view illustrating an example in which the heat dissipation assembly according to one embodiment is applied.

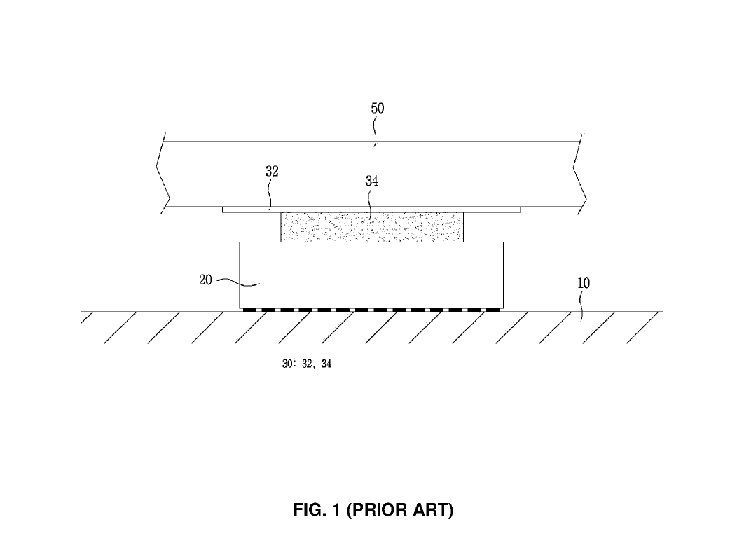

Referring to FIG. 1, the heat dissipation assembly 100 includes a metal pad 110, at which a protrusion 112 is formed, and thermal interface materials 120 and 130 which adhere to top and bottom surfaces of the protrusion 112 to be modulated.

<Metal Pad 110>

The metal pad 110 may be fixed to a surface of a metal case 50 using a thermally conductive adhesion tape, a thermally conductive adhesive, a screw, or welding. As the welding, ultrasonic welding or laser welding may be applied.

The case 50 may be, for example, a metal case of a smart phone, and an insulating layer may be formed or not be formed on the entire surface thereof for preventing corrosion.

The case 50 may include a metal material and may include functions of cooling, heat dispersion, and electromagnetic interference shielding simultaneously.

The metal pad 110 may include a core formed of any one of copper, a copper alloy, aluminum, and an aluminum alloy and a plating layer formed at an outermost part by sequentially plating nickel and gold or plating tin or silver to surround the core.

The protrusion 112 is formed at a certain part of the metal pad 110 and protrudes to form, for example, a top surface having a similar size and shape to those of the thermal interface material 120 which adheres thereto.

Referring to FIG. 2B, a body of the metal pad 110 is pushed and pressurized from a bottom surface to a top surface of the metal pad 110 such that the protrusion 112 is formed.

According to the above structure, since it is possible to reduce a height of the thermal interface material 120 as much as a height of the protrusion 112, the thermal interface material 120 may be adequately endure an external shock and may maintain a general height overall.

The protrusion 112 may be formed to be integrated with the metal pad 110 using a drawing mold and a press and may have a height higher than a height of the thermal interface material 120.

<Thermal Interface Material 120>

The thermal interface material 120 includes flexibility and elasticity to adhere to the top surface of the protrusion 112 of the metal pad 110 and comes into direct contact with a heating source 20 to quickly transfer heat generated by the heating source 20 to the protrusion 112 of the metal pad 110.

As the thermal interface material 120, for example, thermally conductive silicone rubber, thermally conductive gel, or the like may be applied. The thermal interface material 120 may be self-adhesive.

<Thermal Interface Material 130>

The thermal interface material 130 adheres to the bottom surface of the protrusion 112 of the metal pad 110 and comes into direct contact with the case 50.

The thermal interface material 130 may be, for example, a thermally conductive silicone rubber or a thermally conductive gel, may be self-adhesive, may function as a filler filled in a gap formed between the metal pad 110 and the case 50, and effectively transfers heat between the metal pad 110 and the case 50.

Particularly, although heat transfer is not efficiently performed due to a poor contact at an interface between the metal pad 110 and the case 50 in a general case, the thermal interface material 130 intervenes in a part of the metal pad 110 such that a contact between the metal pad 110 and the case 50 is improved in the embodiment.

Particularly, when the metal pad 110 is mounted on the case 50 through soldering or welding, the metal pad 110 before being mounted may be temporarily fixed to a precise position of the case 50.

Although the thermal interface material 120 comes into contact with the heating source 20 has been described as an example as shown in FIG. 3 in the embodiment, the present invention is not limited thereto and the thermal interface material 130 may come into contact with the heating source 20. In this case, unlike FIG. 3, the metal pad 110 adheres to the heating source 20 with, for example, a thermally conductive adhesion tape intervening therebetween, the thermal interface material 130 adheres to the heating source 20 using self-adhesiveness, and the thermal interface material 120 adheres to the case 50.

In the embodiment, a surface area of the thermal interface material 120 may be larger than a surface area of the thermal interface material 130, and a height of the thermal interface material 120 may be higher than a height of the thermal interface material 130.

Also, the thermal interface materials 120 and 130 may include silicone rubber including thermally conductive carbon fibers having a length longer than a diameter.

In this case, according to the embodiment, since the thermal interface materials 120 and 130 including high-priced carbon fibers may be less used as much as a thickness of the metal pad 110 and a probability of coming into contact with an outside is low as much as a height of the metal pad 110, mechanical stability is present.

Also, thermal conductivity is high when carbon fibers of the thermal interface materials 120 and 130, which have high thermal conductivity in a longitudinal direction, are aligned such that the longitudinal direction thereof is to be like a height direction of the thermal interface materials 120 and 130. Here, heights of the thermal interface materials 120 and 130 become low due to the protrusion 112 such that thermal conductivity of the thermal interface materials 120 and 130 becomes high due to the protrusion 112.

A length of the carbon fibers may be 0.02 mm to 0.05 mm, and the heights of the thermal interface materials 120 and 130 may be about 1 mm.

Meanwhile, in the embodiment, an electrically conductive rubber, an electrically conductive gasket formed of an electrically conductive film, an electrically conductive gasket formed of electrically conductive fibers, or an electrically conductive sponge may be installed at a part of the metal pad 110, at which the protrusion 112 does not protrudes.

Hereinafter, an operation of the heat dissipation assembly 100 having the above-described structure will be described with reference to FIGS. 2A to 3.

The heat dissipation assembly 100 is applied to the heating source 20 mounted on a circuit board 10 and operates such that heat generated by the heating source 20 is transferred to the case 50 through the thermal interface material 120, the metal pad 110, and the thermal interface material 130 to be cooled and dispersed.

In consideration of a process of installing the heat dissipation assembly 100, the heat dissipation assembly 100 in which the thermal interface materials 120 and 130 adhere to the top and bottom surfaces of the protrusion 112 of the metal pad 110 is prepared. When the thermal interface material 130 of the metal pad 110 is disposed at a preset position of the case 50, for example, a position corresponding to the heating source 20, the thermal interface material 130 is temporarily fixed to the case 50 through self-adhesiveness.

Subsequently, the metal pad 110 is fixed to the case 50 using welding, soldering, or a double-sided adhesive tape.

As a result thereof, the metal pad 110 is fixed to the surface of the metal case 50 such that the heat dissipation assembly 100 and the metal case 50 are mechanically and thermally coupled with each other.

According to the above components, the heat generated by the heating source 20 is transferred to the case 50 through one heat transfer path including the thermal interface material 120 and the metal pad 110 and uses another heat transfer path including the thermal interface material 120, the metal pad 110, and the thermal interface material 130 simultaneously.

As a result thereof, the heat transfer path including a metal having very excellent heat conductivity is configured and the thermal interface material intervenes between interfaces of the metal pad and the case such that thermal contact is improved and heat is quickly transferred and dissipates.

Also, since the heat dissipation assembly 100 includes the metal pad 110 and the thermal interface material 120 and is modulated to perform heat dissipation, a manufacturer that manufactures electronic devices only has to receive and mount the heat dissipation assembly 100 on the case 50 through welding such that manufacturing efficiency is improved.

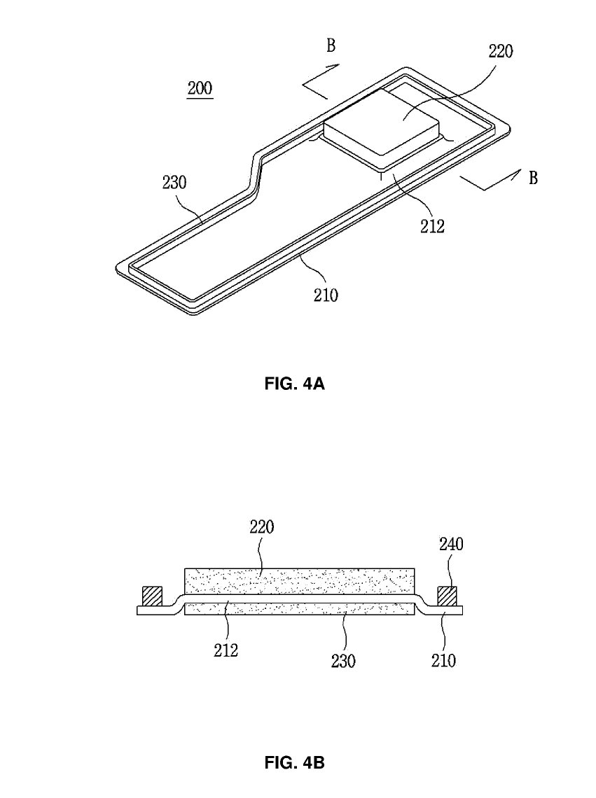

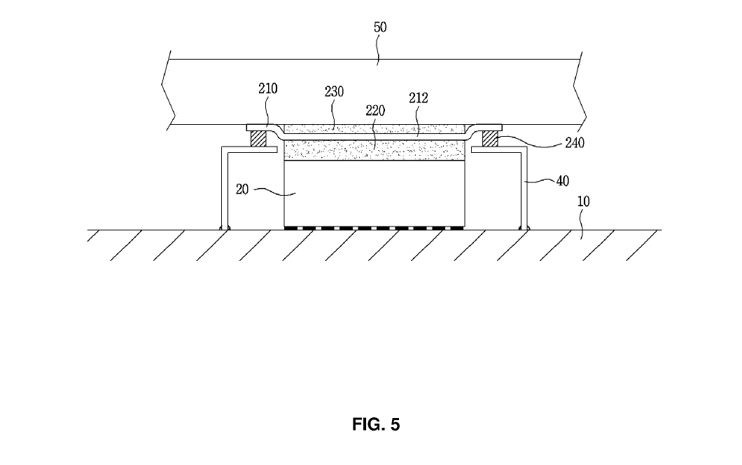

FIG. 4A is a perspective view of a heat dissipation assembly according to another embodiment of the present invention, FIG. 4B is a cross-sectional view taken along A-A in FIG. 4A, and FIG. 5 is a view illustrating an example in which the heat dissipation assembly according to another embodiment is applied.

Hereinafter, a description on components which overlap with those of the above one embodiment will be omitted and only other components will be described.

Referring to FIGS. 4A and 4B, a heat dissipation assembly 200 includes a metal pad 210 at which a protrusion 212 is formed, thermal interface materials 220 and 230 which adhere to top and bottom surfaces of the protrusion 212 respectively, and an elastic gasket 240 installed on the metal pad 210 to form a loop along an edge thereof.

<Elastic Gasket 240>

The elastic gasket 240 forms a loop on the metal pad 210 along an edge thereof and comes into contact with a shield can 40 to prevent electromagnetic interference from flowing from the outside or to prevent electromagnetic interference generated by the heating source 20 from flowing out to the outside.

The loop may be a closed loop like the embodiment, but is not limited thereto, and may be a partially opened loop.

The elastic gasket 240 may be, for example, an electrically conductive rubber, an electrically conductive sponge, or an electrically conductive film and is not limited thereto.

When the elastic gasket 240 is an electrically conductive rubber, the elastic gasket 240 may be formed by curing an electrically conductive liquid rubber corresponding thereto and adhering to the metal pad 210.

A compression range of the elastic gasket 240 may be 20% or more of an original height, and heat conductivity thereof may be 0.5 W/mk or higher.

Hereinafter, an operation of the heat dissipation assembly 200 having the above-described structure will be described with reference to FIG. 5.

The heat dissipation assembly 200 is applied to the heating source 20 mounted on the circuit board 10 and the shield can 40 which is mounted on the circuit board 10 and encloses the heating source 20 and includes an opening at a top surface.

Here, the shield can 40 may be, for example, mounted on a ground pattern of the circuit board 10 through reflow soldering.

According to the above components, the heat generated by the heating source 20 is transferred to the case 50 through one heat transfer path including the thermal interface material 220 and the metal pad 210 and uses another heat transfer path including the thermal interface material 220, the metal pad 210, and the thermal interface material 230 simultaneously.

As a result thereof, the heat transfer path including a metal having very excellent heat conductivity is configured and the thermal interface material intervenes between interfaces of the metal pad and the case such that thermal contact is improved and heat is quickly transferred and dissipates.

Additionally, it is possible to effectively prevent electromagnetic interference which flow from the outside or electromagnetic interference generated by electronic components which form the heating source 20 from flowing out to the outside, using the metal pad 210, the shield can 40, and the elastic gasket 240 through grounding of the circuit board 10.

Meanwhile, since the heat dissipation assembly 200 includes the metal pad 210, the thermal interface materials 220 and 230, and the elastic gasket 240 and is modulated to perform heat dissipation and electromagnetic interference interception, a manufacturer that manufactures electronic devices only has to receive and mount the heat dissipation assembly 200, which is reel-taped to a carrier, on the case 50 through welding such that manufacturing efficiency is improved.

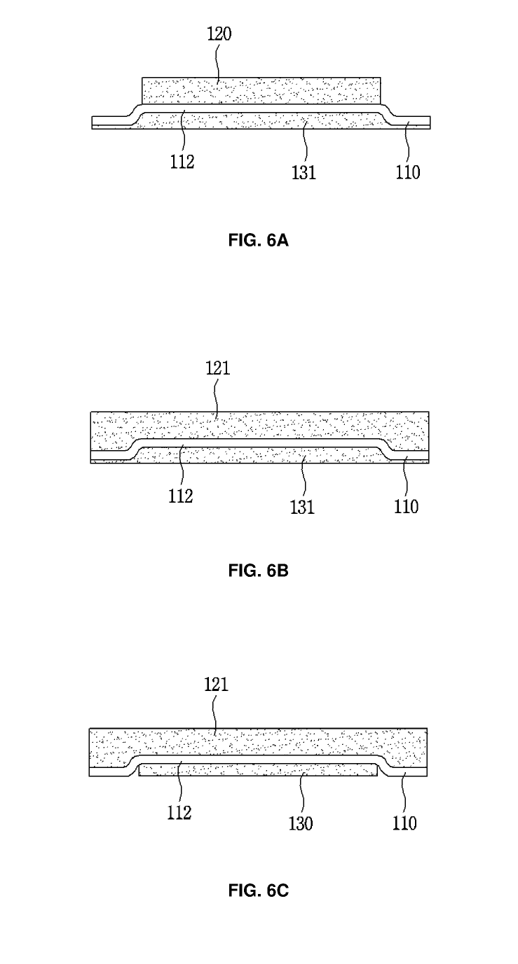

FIGS. 6A to 6C are views of a plurality of heat dissipation assemblies according to other embodiments.

Referring to FIG. 6A, a thermal interface material 131 which adheres to the bottom surface of the protrusion 112 extends to an edge of the metal pad 110. According to this structure, the thermal interface material 131 intervenes in a part at which the metal pad 110 and the metal case 50 come into direct contact with each other such that electrical contact may be reliably performed.

Referring to FIG. 6B, both thermal interface materials 121 and 131 which adhere to the top and bottom surfaces of the protrusion 112 extend toward the edge of the metal pad 110. Like the above embodiment, electrical contact between the metal pad 110 and the metal case 50 may be reliably performed by the thermal interface material 131, and an area in contact with the heating source 20 may be increased by the thermal interface material 121.

Referring to FIG. 6C, the thermal interface material 121 which adheres to the top surface of the protrusion 112 extends toward the edge of the metal pad 110. Like the above embodiment, an area contact with the heating source 20 may be increased by the thermal interface material 121.

Although at least one of the first and second thermal interface materials 121 and 131 extends toward the edge of the metal pad 110 in the embodiment, it is unnecessary to extend all edges of the first and second thermal interface materials 121 and 131, and only parts thereof may be extended.

Also, the first and second thermal interface materials 121 and 131 may not precisely extend to the edge of the metal pad 110 and may extend to only a part adjacent to the edge.

According to the above structure, heat generated by a heating source is transferred to a case through one heat transfer path formed of a first thermal interface material and a metal pad and uses another heat transfer path formed of the first thermal interface material, the metal pad, and a second thermal interface material simultaneously.

As a result thereof, a heat transfer path including a metal having very excellent heat conductivity is configured and a variety of thermal interface materials intervene between interfaces of the metal pad and the case such that thermal contact is improved and heat is quickly transferred and dissipates.

Also, resultingly, since heights of the thermal interface materials are low, there are advantages such as less external interference and easily providing soft thermal interface materials.

Also, one or more thermal interface materials and a metal pad with a protrusion are applied such that it is easy to provide a variety of thermal, electrical, and mechanical functions.

Also, when it is possible to reel-tape a heat dissipation assembly including a metal pad and thermal interface materials, the heat dissipation assembly may be mounted on a metal case through an automated process such as vacuum pickup and the like such that manufacturing efficiency is improved.

Also, it is possible to effectively prevent electromagnetic interference which flow in or out from or to the outside using a metal pad, a shield can, and an elastic gasket.

Although the embodiments of the present invention have been described above, it is apparent that a variety of changes and modifications may be made by one of ordinary skill in the art without departing from the essential features of the present invention. Accordingly, the embodiments disclosed herein are not intended to limit but explain the technical concept of the present invention, and the scope of the present invention should not be limited by the above embodiments. The scope of the present invention should be interpreted by the following claims and all technical concepts within the equivalent scope thereof should be included in the scope of the present invention.

What is claimed is:

1. A heat dissipation assembly, which is applied to a heating source mounted on a circuit board, comprising:
a metal pad which has one surface protruding to form a protrusion and the other surface fixed to an object;
a first thermal interface material which adheres to the protrusion at the one surface; and
a second thermal interface material which adheres to the protrusion at the other surface,
wherein the first thermal interface material comprises flexibility and elasticity and comes into elastic contact with a surface of the heating source, and
wherein heat generated by the heating source is transferred to the object through a first heat transfer path formed of the first thermal interface material and the metal pad and a second heat transfer path formed of the first thermal interface material, the metal pad, and the second thermal interface material, to be cooled and dissipate.

2. The heat dissipation assembly of claim 1, wherein the metal pad is fixed to the object through a thermally conductive adhesive tape, a thermally conductive adhesive, soldering, a screw, or welding.

3. The heat dissipation assembly of claim 1, wherein the protrusion is formed to be integrated with the metal pad by a drawing mold and a press.

4. The heat dissipation assembly of claim 1, wherein the metal pad comprises any one of copper, a copper alloy, aluminum, and an aluminum alloy and is plated with nickel, tin, silver, or gold at an outer surface thereof.

5. The heat dissipation assembly of claim 1, wherein at least one of the first and second thermal interface materials has self-adhesiveness.

6. The heat dissipation assembly of claim 1, wherein a surface area of the first thermal interface material is larger than a surface area of the second thermal interface material.

7. The heat dissipation assembly of claim 1, wherein a height of the first thermal interface material is higher than a height of the second thermal interface material.

8. The heat dissipation assembly of claim 1, wherein at least one of the first and second thermal interface materials comprises a silicone rubber comprising thermally conductive carbon fibers having a length longer than a diameter.

9. The heat dissipation assembly of claim 1, wherein the first thermal interface material is formed to extend toward an edge of the metal pad.

10. A heat dissipation assembly, which is applied to a heating source mounted on a circuit board and a shield can which is mounted on the circuit board to enclose the heating source and has an opening at a top surface, the heat dissipation assembly comprising:
a metal pad which has one surface protruding to form a protrusion and the other surface fixed to an object;
a first thermal interface material which adheres to the protrusion at the one surface;
a second thermal interface material which adheres to the protrusion at the other surface; and
an elastic gasket configured to form a closed loop or a partially opened loop along an edge on surface of the metal pad and comes into contact with the shield can,
wherein the first thermal interface material comprises flexibility and elasticity and comes into elastic contact with a surface of the heating source, and
wherein heat generated by the heating source is transferred to the object through a first heat transfer path formed of the first thermal interface material and the metal pad and a second heat transfer path formed of the first thermal interface material, the metal pad, and the second thermal interface material, to be cooled and dissipate.

11. The heat dissipation assembly of claim 10, wherein the elastic gasket is one of an electrically conductive rubber, an electrically conductive gasket formed of an electrically conductive film, an electrically conductive gasket formed of electrically conductive fibers, and an electrically conductive sponge.

12. The heat dissipation assembly of claim 11, wherein the electrically conductive rubber is formed by curing an electrically conductive liquid rubber corresponding to the electrically conductive rubber and adhering to the metal pad.

13. A heat dissipation assembly, which is applied to a heating source mounted on a circuit board, comprising:
a metal pad which has one surface protruding to form a protrusion and the other surface fixed to an object;
a first thermal interface material which adheres to the protrusion at the one surface; and
a second thermal interface material which adheres to the protrusion at the other surface,
wherein the first thermal interface material comprises flexibility and elasticity and comes into elastic contact with a surface of the heating source,
wherein the second thermal interface material is formed to extend toward an edge of the metal pad, and
wherein heat generated by the heating source is transferred to the object through a heat transfer path formed of the first thermal interface material, the metal pad, and the second thermal interface material, to be cooled and dissipate.
